(19) United States
(12) Patent Application Publication
(10) Pub. No.: US 2026/0201570 A1
(43) Pub. Date: Jul. 16, 2026

(54) COMPOSITION FOR SELECTIVELY REMOVING OXIDE COMPOUNDS AND ETCHING RESIDUES OF ONE OR BOTH OF CO AND CU

(71) Applicant: BASF SE, Ludwigshafen am Rhein (DE)

(72) Inventors: Chia Wei CHANG, Taoyuan City (TW); Meng Ju YU, Taoyuan City (TW); Tung I WONG, Taoyuan City (TW); Cheng Shun CHEN, Taoyuan City (TW); Jhih Jheng KE, Taoyuan City (TW)

(21) Appl. No.: 19/137,025

(22) PCT Filed: Dec. 21, 2023
(86) PCT No.: PCT/EP2023/087231

§ 371 Date: Jun. 9, 2025

(30) Foreign Application Priority Data
Dec. 29, 2022 (EP) 22217094.6

(51) Int. Cl. C23F 1/18; C23F 1/30; H10P 70/00

(52) U.S. Cl. CPC C23F 1/18; C23F 1/30; H10P 70/27

(57) ABSTRACT

Described herein are a composition for selectively removing oxide compounds and etching residues of Co and Cu in the presence of one or more of Co, Cu, W, Ru, and Mo, a method of using the composition for selectively removing oxide compounds and etching residues of Co and Cu in the presence of one or more of Co, Cu, W, Ru, and Mo in a process for the manufacture of a semiconductor device, and a process for the manufacture of a semiconductor device, including the step of selectively removing oxide compounds and etching residues of Co and Cu in the presence of one or more of Co, Cu, W, Ru, and Mo.

Described are a composition for selectively removing oxide compounds and etching residues of one or both of Co and Cu in the presence of one or more metals selected from the group consisting of Co, Cu, W, Ru and Mo, the use of said composition for selectively removing oxide compounds and etching residues of one or both of Co and Cu in the presence of one or more metals selected from the group consisting of Co, Cu, W, Ru and Mo in a process for the manufacture of a semiconductor device, and a process for the manufacture of a semiconductor device, said process comprising the step of selectively removing oxide compounds and etching residues of one or both of Co and Cu in the presence of one or more metals selected from the group consisting of Co, Cu, W, Ru and Mo.

In semiconductor manufacturing, the International Technology Roadmap for Semiconductors defines the 7 nm process as the MOSFET technology node following the 10 nm node. It is based on FinFET (fin field-effect transistor) technology, a type of multi-gate MOSFET technology. The 7-nm and sub-7 nm IC process technologies are expected to offer significantly reduced power consumption as well as remarkably increased switching performance and higher density.

In sub-7 nm IC process technology, new materials such as cobalt Co and tungsten W have been introduced for achieving a better performance of integrated circuits. However, those materials are sensitive to oxidation, which is difficult to be controlled in a wet cleaning process. Thus, in wet cleaning processes, when an aqueous cleaning composition is applied for removing oxide compounds and etching residues resulting from etching, especially dry etching, of one or both of Co and Cu, undesired formation of recesses and pit corrosion are normally observed on interconnects comprising cobalt. In addition, interconnect materials such as tungsten are damaged while exposed to the cleaning solution, which seriously influence the yield and quality of an IC manufacturing process.

US 2020/0339523 A1 discloses a composition for selectively etching a layer comprising an aluminum compound in the presence of a layer of a low-k material and/or a layer comprising copper and/or cobalt. Said composition comprises one or more etchants comprising fluoride anions; preferably ammonium fluoride.

US 2015/0159124 A1 discloses a cleaning composition for cleaning a semiconductor substrate which was subjected to plasma-etching, said composition comprising:
1) at least one redox agent;
2) at least one first chelating agent, the first chelating agent being a polyaminopolycarboxylic acid;
3) at least one second chelating agent different from the first chelating agent, the second chelating agent comprising at least two nitrogen-containing groups;
4) at least one metal corrosion inhibitor, the metal corrosion inhibitor being a substituted or unsubstituted benzotriazole;
5) at least one organic solvent selected from the group consisting of water soluble alcohols, water soluble ketones, water soluble esters, and water soluble ethers; 6) water; and
7) optionally, at least one pH adjusting agent, the pH adjusting agent being a base free of a metal ion
wherein the pH of the composition is preferably between 6 and about 11.

US 2015/0159124 A1 does not show that the proposed cleaning composition is suitable for selectively removing oxide compounds and etching residues of one or both of Co and Cu, especially in the presence of one or more metals selected from the group consisting of Co, Cu, W, Ru, and Mo.

US 2017/0200601 A1 discloses an aqueous cleaning composition, comprising at least one non-ionic surfactant corrosion inhibitor, at least one etchant source, at least one passivating agent, water, optionally at least one organic solvent, optionally at least one buffering species, optionally at least one additional corrosion inhibitor, and optionally at least one oxidizing agent, wherein said aqueous cleaning composition is suitable for cleaning post-plasma etch residue from a microelectronic device having said residue thereon. Preferably the at least one etchant comprises a fluoride species selected from the group consisting of hydrofluoric acid, fluoroboric acid, tetramethylammonium hexafluorophosphate, ammonium fluoride, ammonium bifluoride, tetrabutylammonium tetrafluoroborate, tetratnethylammonium tetrafluoroborate, tetraethylammonium tetrafluoroborate, tetrapropylammonium tetrafluoroborate, tetrabutylammonium tetrafluoroborate, tetratnethylammonium tetrafluoroborate, tetraethylammonium tetrafluoroborate, tetrapropylammonium tetrafluoroborate, tetrabutylammonium tetrafluoroborate, and combinations thereof.

WO 2015/060954 A1 discloses a cleaning composition that contains
1) at least one chelating agent, the chelating agent being a polyaminopolycarboxylic acid; 2) at least one organic solvent selected from the group consisting of water soluble alcohols, water soluble ketones, water soluble esters, and water soluble ethers;
3) at least one monocarboxylic acid containing a primary or secondary amino group and at least one additional basic group containing nitrogen;
4) at least one metal corrosion inhibitor, the metal corrosion inhibitor being a substituted or unsubstituted benzotriazole; and
5) water.

EP 3 664 125 A1 discloses a liquid composition, which comprises tetrafluoroboric acid in an amount of 0.01 to 30% by mass, or boric acid and hydrogen fluoride at a ratio of (boric acid)/(hydrogen fluoride) of (0.0001 to 5.0% by mass)/(0.005 to 5.0% by mass), and which has a pH value of 0.0 to 4.0.

US 2015/290765 A1 discloses a rinse liquid having pH 8 or higher and containing following components (A) to (F):
(A) tetramethyl ammonium hydroxide
(B) diamines selected from a group including ethylenediamin and 1,2-di aminopropane
(C) organic acid selected from a group including oxalic acid, citric acid, tartaric acid, malic acid, and picoline acid
(D) histidine or a derivative thereof
(E) at least one kind selected from a group including benzotriazol, imidazole, triazole, tetrazole, and derivative thereof
(F) water.

There is an ongoing need for cleaning compositions which are capable of selectively removing oxide compounds and etching residues of one or both of Co and Cu, wherein said cleaning composition has good compatibility with interconnect materials selected from the group consisting of the metals Co, Cu, W, Ru and Mo.

These and other objects are achieved by the composition disclosed herein. Said composition for selectively removing oxide compounds and etching residues of one or both of Co and Cu in the presence of one or more metals selected from the group consisting of Co, Cu, W, Ru, and Mo comprises
(A) one or more compounds selected from the group consisting of benzotriazoles,
(B) one or more compounds not having a triazole structure, which are selected from the group consisting of compounds having one or more of primary and secondary amine groups with the proviso that said compound has at least three carbon atoms when it has only one primary amino group,
(C) one or more compounds selected from the group consisting of carboxylic acids and chelating agents,
(D) one or more water-miscible organic solvents
(E) water,
wherein the total concentration of compounds comprising a fluorine-containing anion is 0.0008 wt % or less based on the total mass of the composition, said composition having a pH value of less than 6.

More specifically, said composition may comprise
(A) one or more compounds selected from the group consisting of benzotriazoles (B) one or more compounds not having a triazole structure, which are selected from the group consisting of compounds having one or more of primary and secondary amine groups, with the proviso that said compound has at least three carbon atoms when it has only one primary amino group, and with the proviso that when said compound has more than one carboxylic group and more than one amino group, it also comprises sulfur
(C) one or more compounds selected from the group consisting of carboxylic acids and chelating agents
(D) one or more water-miscible organic solvents
(E) water.

Constituent (A) of the above-defined composition consists of one or more compounds which act as corrosion inhibitors and are selected from the group consisting of benzotriazoles which includes 1H-benzotriazole (unsubstituted benzotriazole) and substituted benzotriazoles.

Constituent (B) of the above-defined composition consists of one or more compounds which act as corrosion inhibitors and do not have a triazole structure. Said one or more compounds of constituent (B) are selected from the group consisting of compounds having one or more of primary and secondary amine groups, with the proviso that said compound has at least three carbon atoms when it has only one primary amino group and with the proviso that when said compound has more than one carboxylic group and more than one amino group, it also comprises sulfur.

Surprisingly it has been found that the combination of one or more first corrosions inhibitors selected from the group consisting of benzotriazoles (constituent (A) as defined above) and one or more second corrosion inhibitors selected from the group consisting of compounds having one or more of primary and secondary amine groups, with the proviso that said compound has at least three carbon atoms when it has only one primary amino group and with the proviso that when said compound has more than one carboxylic group and more than one amino group, it also comprises sulfur (constituent (B) as defined above) enables simultaneous protection of a wide variety of interconnect materials selected from metals of the group consisting of Co, Cu, W, Ru and Mo from being damaged in the process of removing oxide compounds and etching residues of one or both of Co and Cu.

Constituent (C) of the above-defined composition consists of one or more compounds which act as etchants for removing oxide compounds and etching residues of one or both of Co and Cu. The compounds of constituent (C) are selected from the group consisting of carboxylic acids and chelating agents. The compounds of constituent (C) do not have a triazole structure and are not polyaminocarboxylic acids. One or more of the compounds of constituent (C) may be selected from compounds having one primary amino group which do not fall under the definition of constituent (B). Polyaminocarboxylic acids as disclosed in US 2015/0159124 A1 are not used as constituent (C). Preferably, constituent (C) consists of carboxylic acids which have no amino groups, more preferably of carboxylic acids which have no nitrogen-containing groups.

Constituent (D) of the above-defined composition consists of one or more organic solvents which are miscible with water at least in a 1:1 weight ratio at 20° C. and ambient pressure.

In certain cases, said composition consists of constituents (A), (B), (C), (D) and (E) as defined above.

A composition as defined above is a homogeneous (i.e. single-phase) liquid under standard conditions (298 K and 101.325 kPa), wherein the constituents (A), (B) and (C) are dissolved in said liquid. The composition as described herein is not a chemical-mechanical polishing composition because it does not contain any solid abrasive. Different from the composition disclosed herein, a chemical-mechanical polishing composition is not a single-phase liquid.

Surprisingly it has been found that a composition comprising or consisting of constituents (A), (B), (C), (D) and (E) as defined above fulfils the above-defined objects.

Preferably, in the composition described herein the concentration of hydroxylamine is 0.1 wt % or less, preferably 0.05 wt % or less, most preferably 0.01 wt % or less, in each case based on the total mass of the composition. Most preferably, the concentration of hydroxylamine is so low that it is not analytically detectable in the composition.

More preferably, the composition described herein does not contain any compound which may act as a redox agent, i.e. a compound that can induce an oxidation and a reduction in a semiconductor cleaning process.

Preferably, in the composition as defined above the total concentration of polyaminopolycarboxylic acids selected from the group consisting of butylenediaminetetraacetic acid, diethylenetriaminepentaacetic acid (DTPA), ethylenediaminetetrapropionic acid, triethylenetetramine hexaacetic acid, 1,3-diamino-2-hydroxypropane-N,N,N′,N′-tetraacetic acid, propylenediaminetetraacetic acid, ethylene diaminetetraacetic acid (EDTA), trans-1,2-diaminocyclohexane tetraacetic acid, ethylendiamine diacetic acid, ethylendiamine dipropionic acid, 1.6-hexamethylene-diamine-N,N,N′,N′-tetraacetic acid, N,N-bis(2-hydroxybenzyl)ethylenediamine-N,N-diacetic acid, diaminopropane tetraacetic acid, 1,4,7,10-tetraazacyclododecane tetraacetic acid, diaminopropanol tetraacetic acid, and (hydroxyethyl)-ethylenediaminetriacetic acid is 0.008 wt % or less, more preferably 0.005 wt % or less, most preferably 0.001% or less, in each case based on the total mass of the composition. Most preferably, the concentration of said polyaminopolycarboxylic acids is so low that they are not analytically detectable in the composition. Further preferably, in the composition as defined above the total concentration of any polyaminopolycarboxylic acids (with the exception of cysteine) is 0.008 wt % or less, more preferably 0.005 wt % or less, most preferably 0.001% or less, in each case based on the total mass of the composition. Most preferably, the total concentration of polyaminopolycarboxylic acids is so low that they are not analytically detectable in the composition.

Preferably, in the composition as defined above the total concentration of compounds comprising a fluorine-containing anion is 0.0008 wt % or less, preferably 0.0005 wt % or less, more preferably 0.0001 wt % or less, in each case based on the total mass of the composition. More preferably, a composition as described herein is free of fluorine-containing anions. Most preferably, the concentration of fluorine-comprising constituents is so low that the element fluorine is not analytically detectable in the composition.

In a composition as described herein, preferably the total amount of constituent (A) is in the range of from 0.5% to 5% based on the sum of the masses of constituents (A), (B), (C), (D) and (E).

In a composition as described herein, preferably the total amount of constituent (B) is in the range of from 500 ppm to 2000 ppm based on the sum of the masses of constituents (A), (B), (C), (D) and (E).

In a composition as described herein, preferably the total amount of constituent (C) is in the range of from 0.01% to 0.1% based on the sum of the masses of constituents (A), (B), (C), (D) and (E).

In a composition as described herein, preferably the total amount of constituent (D) is in the range of from 5% to 20% based on the sum of the masses of constituents (A), (B), (C), (D) and (E).

Most preferably, in a composition as defined above,
the total amount of constituent (A) is in the range of from 0.5% to 5%,
and
the total amount of constituent (B) is in the range of from 500 ppm to 2000 ppm,
and
the total amount of constituent (C) is in the range of from 0.01% to 0.1%,
and
the total amount of constituent (D) is in the range of from 5% to 20%,
in each case based on the sum of the masses of constituents (A), (B), (C), (D) and (E).

In a composition as defined above which consists of constituents (A), (B), (C), (D) and (E), the concentrations of constituents (A), (B) C) and (D) may be in the above-defined ranges, and water (E) makes up for the balance.

Preferably, the one or more compounds of constituent (A), which act as corrosion inhibitors are selected from the group consisting of
(i) unsubstituted benzotriazole
and
(ii) benzotriazoles substituted by one or two substituents which are independently selected from the group consisting of C₁₋₄ alkyl, amino-C₁₋₄ alkyl, phenyl, halogen, hydroxy, nitro and thiol.

Preferably, all compounds of constituent (A) are selected from the above-defined group.

More preferably the one or more compounds of constituent (A) which act as corrosion inhibitors are selected from the group consisting of 1H-benzatriazole (i.e. unsubstituted benzotriazole), 6-methyl-benzotriazole, 5-methyl-benzotriazole, 5,6-dimethyl-1H-benzotriazole, 1-hydroxybenzotriazole, 5-phenyl-benzotriazole, 5-nitro-benzotriazole, 2-(5-aminopentyl)-benzotriazole, 5-nitro-1-phenyl-1H-benzotriazole, and 5-halobenzotriazoles (e.g. 5-chlorobenzotriazole).

Preferably, all compounds of constituent (A) are selected from the above-defined preferred group.

Preferably, the one or more compounds of constituent (B), which act as corrosion inhibitors are selected from the group consisting of
2-amino acids having three or more carbon atoms, e.g. histidine, including sulfur-containing amino acids, e.g. cysteine
di- and tripeptides of 2-aminoacids, e.g. gluthathione
disulfides of sulfur-containing 2-amino acids, e.g. cystine
and biguanides of formula (I)

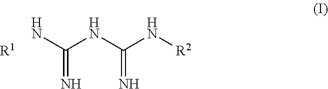

wherein
R¹ is selected from the group consisting of H, C₁₋₆-alkyl, phenyl, halophenyl (e.g. chlorophenyl) and C₁₋₃-alkylphenyl
R² is selected from the group consisting of H, C₁₋₆-alkyl, phenyl, halophenyl (e.g. chlorophenyl), C₁₋₃-alkylphenyl and biguanidine group (I′)

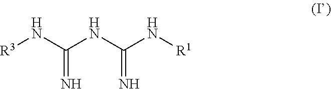

wherein
R¹ is selected from the group consisting of H, C₁₋₆-alkyl, phenyl, halophenyl (e.g. chlorophenyl) and C₁₋₃-alkylphenyl, and
R³ is C₁-C₈ alkylene.

In certain cases, it is preferred that the biguanide as defined above is a biguanide of formula (II)

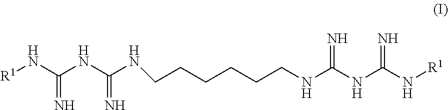

wherein each R¹ is independently selected from the group consisting of H, C₁₋₆-alkyl, phenyl, halophenyl (preferably chlorophenyl) and C₁₋₃-alkylphenyl. Preferably both R¹ of the biguanide of formula (II) are the same.

A preferred example of biguanides of formula (II) is chlorhexidine (i.e. 1,1′-Hexamethylene bis[5-(4-chlorphenyl)biguanide).

Preferably, all compounds of constituent (B) are selected from the above-defined group.

Especially preferably, the one or more compounds of constituent (B), which act as corrosion inhibitors are selected from the group consisting of biguanides of formula (II) (e.g. chlorhexidine (i.e. 1,1′-Hexamethylene bis[5-(4-chlorphenyl)biguanide), histidine, glutathione, cysteine, and cystine. Chlorhexidine (i.e. 1,1′-Hexamethylene bis[5-(4-chlorphenyl)biguanide) is most preferred.

Preferably, all compounds of constituent (B) are selected from the above-defined preferred group.

Preferably, the one or more compounds of constituent (C), which act as etchants are selected from the group consisting of citric acid, oxalic acid, glycolic acid, lactic acid, ethylene diamine tetra(methylene phosphonic acid) (EDTMP), succinic acid, malonic acid, nitrilotriacetic acid, methylsulfonic acid, lactic acid, propionic acid, formic acid, acetic acid, sulfosalicylic acid, salicylic acid, ascorbic acid and glycine.

Preferably, all compounds of constituent (C) are selected from the above-defined group.

Preferably, constituent (C) consists of carboxylic acids which have no amino groups, more preferably of carboxylic acids which have no nitrogen-containing groups. Thus, diamine tetra(methylene phosphonic acid) (EDTMP), glycine and nitrilotriacetic acid are less preferred in certain cases.

The one or more organic water-miscible solvents of constituent (D) are preferably selected from the group consisting of ethanol, isopropanol, n-propanol, 1,4-butanediol, diethylene glycol butyl ether, propylene glycol monomethyl ether, dipropylene glycol monomethyl ether, 4 methylmorpholine-4-oxide, trimethylamine-N-oxide, triethylamine-N-oxide, triethanolamine-N-oxide, pyridine-N-oxide, N-formyl-morpholine, N-ethylmorpholine-N-oxide, N-ethylpyrrolidine-N-oxide, dimethyl sulfoxide, dipropylsulfoxide, diethylsulfoxide, methylethyl-sulfoxide, diphenylsulfoxide, methylphenylsulfoxide and 1,1′ dihydroxyphenyl sulfoxide.

Preferably, all solvents of constituent (D) are selected from the above-defined group.

In preferred compositions,
one, more or all compounds of constituent (A) are selected from the above-disclosed preferred group, and
one, more or all compounds of constituent (B) are selected from the above-disclosed preferred group, and
one, more or all compounds of constituent (C) are selected from the above-disclosed preferred group, and
one, more or all solvents of constituent (D) are selected from the above-disclosed preferred group.

Preferably, a composition as described herein has a pH value of less than 6, preferably in the range of from 2 to 5.5, more preferably in the range of from 2 to 5, further preferably from 2.5 to 4.5, most preferably from 2.5 to 4, especially preferably 2.8 to 3.7, as measured by a pH meter at 25° C. and 101.325 kPa.

According to the Pourbaix diagram, tungsten is more effectively prevented from corrosion at an acid pH in the above-mentioned preferred range, compared to the higher pH range of the composition according to US 2015/0159124 A1.

Especially preferred is a composition, comprising or consisting of
(A) one or both of 1H-benzatriazole and 5-methyl-1H-benzotriazole, wherein the total amount of 1H-benzatriazole and 5-methyl-1H-benzotriazole is in the range of from 0.5% to 5%
(B) one or both of histidine and chlorhexidine, wherein the total amount of histidine and chlorhexidine is in the range of from 500 ppm to 2000 ppm
(C) one or both of lactic acid and glycolic acid, wherein the total amount of lactic acid and glycolic acid is in the range of from 0.01% to 0.1%
(D) one or both of N-formyl-morpholine and dimethylsulfoxide, wherein the total amount of N-formyl-morpholine and dimethylsulfoxide is in the range of from 5% to 20%
(E) water
in each case based on the sum of the masses of constituents (A), (B), (C), (D) and (E).

Preferably, said composition has a pH in the range of from 2 to 5, further preferably from 2.5 to 4.5, most preferably from 2.5 to 4, especially preferably 2.8 to 3.7, as measured by a pH meter at 25° C. and 101.325 kPa.

According to a further aspect, the present disclosure relates to the use of a composition as defined above for selectively removing oxide compounds and etching residues of one or both of Co and Cu in the presence of one or more metals selected from the group consisting of as Co, Cu, W, Ru and Mo in a process for the manufacture of a semiconductor device. Preferably, the semiconductor device is manufactured by means of sub-7 nm IC process technology as mentioned above. Preferably, the semiconductor device is or comprises an integrated circuit (IC).

Regarding specific and preferred compositions for the above-defined use, reference is made to the disclosure provided above in the context of the description of the composition for selectively removing oxide compounds and etching residues of one or both of Co and Cu in the presence of one or more metals selected from the group consisting of Co, Cu, W, Ru, and Mo.

In the above-defined use, the oxide compounds may comprise oxides of one or both of Cu and Co.

In the above-defined use, the etching residues may comprise fluorides of one or both of Cu and Co. Such etching residues are typically formed in dry etching processes.

In the above-defined use, the semiconductor device may comprise one or more interconnects comprising one or both of Co and Cu.

In the above-defined use, the semiconductor device may comprise one or more interconnects comprising one or more of W, Ru and Mo.

In the above-defined use, the semiconductor device may comprise one or more dielectric materials selected from the group consisting of polycrystalline Si, SiO₂ and Si₃N₄.

More specifically, in the above-defined use the semiconductor device may comprise
one or more first interconnects comprising one or both of Co and Cu, and
one or more second interconnects comprising one or more of W, Ru and Mo, and
one or more dielectric materials selected from the group consisting of polycrystalline Si, SiO₂ and Si₃N₄.

According to a further aspect, the present disclosure relates to a process for the manufacture of a semiconductor device, comprising the step of selectively removing oxide compounds and etching residues of one or both of Co and Cu in the presence of one or more metals selected from the group consisting of Co, Cu, W, Ru and Mo by applying a composition as defined above. Preferably, the semiconductor device is or comprises an integrated circuit (IC).

Regarding specific and preferred compositions for the above-defined process, reference is made to the disclosure provided above in the context of the description of the composition.

Preferably, the semiconductor device is manufactured by means of sub-7 nm IC process technology as mentioned above.

Typically, in the above-defined process the above-defined composition is applied for cleaning a surface of the semiconductor device or its precursor after a step of dry etching. Thus, a process for the manufacture of a semiconductor device as described herein may comprise the steps of
dry etching a surface of the semiconductor device or its precursor
selectively removing oxide compounds and etching residues of one or both of Co and Cu in the presence of one or more metals selected from the group consisting of Co, Cu, W, Ru and Mo by applying a composition as defined above to the surface which was subject to dry etching.

In the above-defined process, applying a composition as defined above to a surface area of a semiconductor device which is to be cleaned may be carried out in any suitable manner using any suitable means. For instance, the composition may be applied by means of dipping (immersing the surface area of a semiconductor device which is to be cleaned into the composition), rinsing, or spraying. Usually, the cleaning step is followed by drying.

In the above-defined process, the oxide compounds may comprise oxides of one or both of Cu and Co.

In the above-defined process, the etching residues may comprise fluorides of one or both of Cu and Co. Such etching residues are typically formed in dry etching processes.

In the above-defined process, the semiconductor device may comprise one or more interconnects comprising one or both of Co and Cu.

In the above-defined process, the semiconductor device may comprise one or more interconnects comprising one or more of W, Ru and Mo.

In the above-defined process, the semiconductor device may comprise one or more dielectric materials selected from the group consisting of polycrystalline Si, SiO₂ and Si₃N₄.

More specifically, in the above-defined process the semiconductor device may comprise
one or more first interconnects comprising one or both of Co and Cu, and
one or more second interconnects comprising one or more of W, Ru and Mo, and
one or more dielectric materials selected from the group consisting of polycrystalline Si, SiO₂ and Si₃N₄.

An especially preferred process according to the present disclosure comprises the step of selectively removing oxide compounds and etching residues of one or both of Co and Cu in the presence of one or more metals selected from the group consisting of Co, Cu, W, Ru and Mo by applying a composition comprising or consisting of
(A) one or both of 1H-benzatriazole and 5-methyl-1H-benzotriazole, wherein the total amount of 1H-benzatriazole and 5-methyl-1H-benzotriazole is in the range of from 0.5% to 5%
(B) one or both of histidine and chlorhexidine, wherein the total amount of histidine and chlorhexidine is in the range of from 500 ppm to 2000 ppm
(C) one or both of lactic acid and glycolic acid, wherein the total amount of lactic acid and glycolic acid is in the range of from 0.01% to 0.1%
(D) one or both of N-formyl-morpholine and dimethylsulfoxide, wherein the total amount of N-formyl-morpholine and dimethylsulfoxide is in the range of from 5% to 20%
(E) water
in each case based on the sum of the masses of constituents (A), (B), (C), (D) and (E).

Preferably, said composition has a pH in the range of from 2 to 5, further preferably from 2.5 to 4.5, most preferably from 2.5 to 4, especially preferably 2.8 to 3.7, as measured by a pH meter at 25° C. and 101.325 kPa.

According to a further aspect, the present disclosure relates to the use of a biguanidine according to formula (I) as defined above, preferably of a biguanidine according to formula (II) as defined above, as corrosion inhibitor for inhibiting the corrosion of tungsten. Preferably, the biguanidine is chlorhexidine (i.e. 1,1′-hexamethylene bis[5-(4-chlorphenyl)biguanide). Surprisingly it has been found that said biguanidines like chlorhexidine, which hitherto have mainly been used for pharmaceutic applications, are efficient corrosion inhibitors for tungsten. Preferably, the biguanidine according to formula (I) as defined above is used in the composition as defined above, and/or in the above-defined process for the manufacture of a semiconductor device as defined above.

### EXAMPLES

The following examples are meant to further explain the invention without limiting its scope.

Compositions as defined above and comparison compositions (for details see the tables below) were applied to samples having
(i) a film consisting of a metal selected from the group consisting of Co, Cu, W, Mo, Ti and Ru, or
(ii) a film consisting of Co covered by its oxides (CoOₓ) resp. Cu covered by its oxides (CuOₓ)
(iii) a non-metal film consisting of TEOS or TiN
in each case deposited on a substrate made of Si
or
(iv) to the bare Si substrate.

The compositions were brought to a temperature of 40° C. and applied to the samples by means of spin-rinsing.

In cases (i) and (ii), the etching rate was determined by measuring the thickness variation as a function of the etching time by means of XRF (X-ray fluorescence) analysis. In case (ii) the slope of the thickness reduction is steep as long as the oxides are etched, and suddenly flattens when the oxides are removed and the metal surface is exposed.

In case (iii) and (iv), the etching rate was determined by measuring the thickness variation as a function of the etching time by means of ellipsometry.

The etching rate is given in Angstroms per minute (A/min).

In tables 1-4, the concentration of all constituents is given in wt % except for those constituents for which it is explicitly indicated that the concentration is given in ppm.

### 1. Screening for Suitable Corrosion Inhibitors for Co

This series of tests has the target to identify efficient corrosion inhibitors for Co. The compositions (not according to the invention) indicated in table 1 were applied to a film consisting of Co deposited on a substrate made of Si. The etching rate was determined as described above (case (i)). In said compositions, the etchant (C) is oxalic acid and the solvent (D) is either N-formyl-morpholine (NFM) or dimethylsulfoxide (DMSO). Each of compositions #1-2 to #1-10 comprises a heterocyclic compound having one or more N atoms in the heterocyclic ring which shall be tested for its efficiency in inhibiting corrosion of Co. Comparison composition #1-1 does not contain a heterocyclic compound having one or more N atoms in the heterocyclic ring. Comparison composition #1-1 is a commonly used cleaning composition for removal of CoOx.

The lower the etching rate of Co, the more efficient is the corrosion inhibitor. Table 1 shows that compounds selected from the group consisting of benzotriazoles are superior corrosion inhibitors for Co, compared to other heterocyclic compounds comprising one or more N atoms in the heterocyclic ring (imidazole and thiazole). Thus, benzotriazole, 5-methyl-1 h-benzotriazole and 5-chlorobenzotriazole are suitable candidates for constituent (A) of the above-defined composition.

TABLE 1

| | Compo- | | | | | | | | | | |
|---|---|---|---|---|---|---|---|---|---|---|---|
| | sition # | | | | | | | | | | |
| CAS No. | constituent | 1-1 | 1-2 | 1-3 | 1-4 | 1-5 | 1-6 | 1-7 | 1-8 | 1-9 | 1-10 |
| 4394-85-8 | NFM | — | 10 | — | 10 | 10 | 10 | 10 | — | 10 | 10 |
| 67-68-5 | DMSO | — | — | 10 | — | — | — | — | 10 | — | — |
| 144-62-7 | oxalic acid | 0.5 | 0.5 | 0.5 | 0.5 | 0.5 | 0.5 | 0.5 | 0.5 | 0.5 | 0.5 |
| 95-14-7 | benzo- | — | 1 | 1 | — | — | — | 1 | 1 | 1 | — |
| | triazole | | | | | | | | | | |
| 136-85-6 | 5-methyl- | — | — | — | 1 | — | — | 1 | 1 | — | — |
| | 1h-benzo- | | | | | | | | | | |
| | triazole | | | | | | | | | | |
| 94-97-3 | 5-chloro- | — | — | — | — | 0.15 | — | — | — | 0.15 | — |
| | benzo- | | | | | | | | | | |
| | triazole | | | | | | | | | | |
| 288-32-4 | Imidazole | — | — | — | — | — | 1 | — | — | — | — |
| 288-47-1 | Thiazole | — | — | — | — | — | — | — | — | — | 1 |
| 7732-18-5 | water | Balance in each case | | | | | | | | | |
| | Co (A/min) | 48.5 | 25.2 | 26.7 | 21.8 | 20.2 | 41.5 | 11.3 | 15.3 | 12.5 | 34 |

### 2. Screening for Suitable Etchants for CoOx

This series of tests has the target to identify efficient etchants for CoOx which have a high selectivity for etching CoOx over etching metallic Co. The compositions (not according to the invention) indicated in table 2 were applied to a film consisting of Co deposited on a substrate made of Si, wherein said film of Co is covered by CoOx. The etching rate was determined as described above (case (ii)). In said compositions, one or both of benzotriazole and 5-methyl-1H-benzotriazole act as corrosion inhibitor (A), and the solvent (D) is N-formyl-morpholine (NFM). Each of compositions #2-2 to #2.11 comprises a compound which shall be tested for its efficiency in selectively etching CoOx as may be formed by dry etching of Co. Comparison composition #2-1 does not contain any compound which may act as an etchant.

TABLE 2

| | Compo- | | | | | | | | | | | |
|---|---|---|---|---|---|---|---|---|---|---|---|---|
| | sition # | | | | | | | | | | | |
| CAS No. | Constituent | 2-1 | 2-2 | 2-3 | 2-4 | 2-5 | 2-6 | 2-7 | 2-8 | 2-9 | 2-10 | 2-11 |
| 4394-85-8 | NFM | 10 | — | — | 10 | 10 | — | 10 | 10 | 10 | 10 | 10 |
| 95-14-7 | benzo- | 1 | 1 | 1 | 1 | 1 | — | 1 | — | 1 | 1 | 1 |
| | triazole | | | | | | | | | | | |
| 136-85-6 | 5-methyl-1H- | 1 | 1 | 1 | 1 | 1 | — | 1 | 1 | 1 | 1 | 1 |
| | benzo- | | | | | | | | | | | |
| | triazole | | | | | | | | | | | |
| 12125-01-8 | NH4F | — | 0.2 | — | — | — | — | — | — | — | — | — |
| 7664-39-3 | HF | — | — | 0.2 | — | — | — | — | — | — | — | — |
| 77-92-9 | Citric | — | — | — | 0.2 | — | — | — | — | — | — | — |
| | acid | | | | | | | | | | | |
| 144-62-7 | Oxalic | — | — | — | — | 0.2 | 0.2 | — | — | — | — | — |
| | acid | | | | | | | | | | | |
| 79-14-1 | glycolic | — | — | — | — | — | — | 0.2 | 0.2 | — | — | — |
| | acid | | | | | | | | | | | |
| 79-33-4 | Lactic | — | — | — | — | — | — | — | — | 0.2 | — | — |
| | acid | | | | | | | | | | | |
| 1429-50-1 | EDTMP | — | — | — | — | — | — | — | — | — | 0.2 | — |
| 110-15-6 | Succinic | — | — | — | — | — | — | — | — | — | — | 0.2 |
| | acid | | | | | | | | | | | |

| | | |
|---|---|---|
| 7732-18-5 | water | Balance in each case |

| | | | | | | | | | | | |
|---|---|---|---|---|---|---|---|---|---|---|---|
| CoOx (A/min) | <0.1 | 0.37 | 14.5 | 50.1 | 28.7 | 39.9 | 16.4 | 18.6 | 11.5 | 24.2 | 13.5 |
| Co (A/min) | 1 | 0.55 | 6.9 | 61.2 | 16.2 | 33.2 | 3.5 | 4.1 | 3.3 | 14.8 | 8.8 |
| selectivity (CoOx/Co) | 0 | 0.7 | 2.1 | 0.8 | 1.8 | 1.2 | 4.7 | 4.5 | 3.5 | 1.6 | 1.5 |

Table 2 shows that glycolic acid and lactic acid have a high selectivity for etching CoOx over etching metallic Co (compositions #2.6, 2.7 and 2.8). Thus, glycolic acid and lactic acid are suitable candidates for constituent (C) of the above-defined composition. In contrast, fluorine-containing etchants as used in prior art (cf. US 2020/0339523A1) have a low selectivity for etching CoOx over etching metallic Co.

### 3. Screening for Suitable Corrosion Inhibitors for W

This series of tests has the target to identify efficient corrosion inhibitors for tungsten (W). The compositions indicated in table 3a were applied to different films each deposited on a substrate made of Si, or to the bare surface of the Si substrate (for details, see table 3b), and the etching rate was determined as described above (case (i), (ii), (iii), (iv), resp.). In said compositions, the etchant (C) is glycolic acid and the solvent (D) is N-formylmorpholine (NFM). Each of compositions #3-2 to #3-11 comprises one or more compounds which shall be tested for its efficiency in inhibiting corrosion of W. Comparison composition #3-1 does not contain any further corrosion inhibitor than benzotriazole.

Table 3b shows that chlorhexidine, histidine, glutathione, cystine and cysteine (compositions #3.2 to #3.7, and #3.9 to #3.11) are superior corrosion inhibitors for W, compared to hexadecyltrimethylammonium hydroxide (composition #3.8, not according to the invention).

Thus, chlorhexidine, histidine, glutathione, cystine and cysteine are suitable candidates for constituent (B) of the above-defined composition.

For comparison, composition FE1 disclosed in US 2015/0159124 A1 was also tested (cf. table 4). Surprisingly, it has a rather high etching rate for tungsten, probably due to the basic pH>6. In addition, its selectivity for etching CuOₓ over metallic Cu is significantly lower than for the compositions according to the invention.

TABLE 3a

| | Compo- | | | | | | | | | | | |
|---|---|---|---|---|---|---|---|---|---|---|---|---|
| | sition # | | | | | | | | | | | |
| | constit- | | | | | | | | | | | |
| CAS No | uent | 3-1 | 3-2 | 3-3 | 3-4 | 3-5 | 3-6 | 3-7 | 3-8 | 3-9 | 3-10 | 3-11 |
| 4394-85-8 | NFM | 10 | 10 | 10 | 10 | 10 | 10 | 10 | 10 | 10 | 10 | 10 |
| 95-14-7 | benzo- | 1 | 1 | 1 | 1 | 1 | 1 | 1 | 1 | 1 | 0.5 | 0.5 |
| | triazole | | | | | | | | | | | |
| 136-85-6 | 5-methyl- | — | — | — | — | — | — | — | — | — | 0.5 | 0.5 |
| | 1H-benzo- | | | | | | | | | | | |
| | triazole | | | | | | | | | | | |
| 79-14-1 | glycolic | 0.2 | 0.2 | 0.2 | 0.2 | 0.2 | 0.2 | 0.2 | 0.2 | 0.2 | 0.2 | 0.2 |
| | acid | | | | | | | | | | | |
| 18472-51-0 | chlor- | — | 50 ppm | 100 ppm | — | 100 ppm | — | — | — | — | — | 100 ppm |
| | hexidine | | | | | | | | | | | |
| 71-00-1 | histidine | — | — | — | 1000 ppm | 1000 ppm | — | — | — | — | 1000 ppm | 1000 ppm |
| 70-18-8 | gluta- | — | — | — | — | — | 100 ppm | — | — | — | — | — |
| | thione | | | | | | | | | | | |
| 56-89-3 | cystine | — | — | — | — | — | — | 100 ppm | — | — | — | — |
| 505-86-2 | hexadecyl- | — | — | — | — | — | — | — | 200 ppm | — | — | — |
| | trimethyl | | | | | | | | | | | |
| | ammo- | | | | | | | | | | | |
| | nium | | | | | | | | | | | |
| | hydroxide | | | | | | | | | | | |
| 52-90-4 | cysteine | — | — | — | — | — | — | — | — | 100 ppm | — | — |
| | water | Balance in each case | | | | | | | | | | |
| | pH | 2.9 | 2.9 | 2.9 | 3.6 | 3.6 | 2.9 | 3.0 | 3.8 | 3.0 | 3.5 | 3.6 |

TABLE 3b

| Composition # | 3-1 | 3-2 | 3-3 | 3-4 | 3-5 | 3-6 | 3-7 | 3-8 | 3-9 | 3-10 | 3-11 |
|---|---|---|---|---|---|---|---|---|---|---|---|
| Co (A/min) | 4.2 | 4 | 4.1 | 3.2 | 3.2 | 3.9 | 4.1 | 2.9 | 4.5 | <0.1 | <0.1 |
| W (A/min) | 7.5 | 1.5 | <0.1 | 3.3 | <0.1 | 4.2 | 3.1 | 6.6 | 2.9 | 3.1 | <0.1 |
| Ru (A/min) | <0.1 | <0.1 | <0.1 | <0.1 | <0.1 | <0.1 | <0.1 | <0.1 | <0.1 | <0.1 | <0.1 |
| Mo (A/min) | 4.1 | 0.5 | <0.1 | 1.2 | <0.1 | 2.8 | 1.1 | 3.8 | 1 | <0.1 | <0.1 |
| TiN (A/min) | <0.1 | <0.1 | <0.1 | <0.1 | <0.1 | <0.1 | <0.1 | <0.1 | <0.1 | <0.1 | <0.1 |
| Ti (A/min) | <0.1 | <0.1 | <0.1 | <0.1 | <0.1 | <0.1 | <0.1 | <0.1 | <0.1 | <0.1 | <0.1 |
| Si (A/min) | <0.1 | <0.1 | <0.1 | <0.1 | <0.1 | <0.1 | <0.1 | <0.1 | <0.1 | <0.1 | <0.1 |
| TEOS (A/min) | <0.1 | <0.1 | <0.1 | <0.1 | <0.1 | <0.1 | <0.1 | <0.1 | <0.1 | <0.1 | <0.1 |
| Cu (A/min) | 2.2 | 1.5 | 1.1 | 1.6 | 1.0 | 0.8 | 2.1 | 2.4 | 0.6 | <0.1 | <0.1 |
| CoOx (A/min) | 18.3 | 18.1 | 18.1 | 17.3 | 17.3 | 17.9 | 18.1 | 14.1 | 18.5 | 17.5 | 17.5 |
| CuOx (A/min) | 14.8 | 13.1 | 15.2 | 14.6 | 14.1 | 15.7 | 13.6 | 19.1 | 14.6 | 14.2 | 14.5 |
| selectivity | 4.4 | 4.5 | 4.4 | 5.4 | 5.4 | 4.6 | 4.4 | 4.9 | 4.1 | >175 | >175 |
| (CoOx/Co) | | | | | | | | | | | |
| selectivity | 6.7 | 8.7 | 13.8 | 9.1 | 14.1 | 19.6 | 6.5 | 8.0 | 24.3 | >142 | >145 |
| (CuOx/Cu) | | | | | | | | | | | |

TABLE 4

| | Composition # |
|---|---|
| | composition FE1 of |
| constituent | US 2015/0159124 A1 |
| Ethylene glycol butyl ether | 5 |
| diethylenetriamine pentaacetic acid | 0.5 |
| 5-methyl-1H-benzotriazole | 0.25 |
| Ethylene glycol butyl ether | 5 |
| chlorhexidine | 100 ppm |
| Hydroxylamine | 4 |
| water | balance |
| pH | 6.83 |
| Co (A/min) | 1.1 |
| W (A/min) | 10.5 |
| Ru (A/min) | <0.1 |
| Mo (A/min) | 5.5 |
| TiN (A/min) | <0.1 |
| Ti (A/min) | <0.1 |
| Si (A/min) | <0.1 |
| TEOS (A/min) | <0.1 |
| Cu (A/min) | 8.1 |
| CoOx (A/min) | 9.6 |
| CuOx (A/min) | 4.1 |
| selectivity (CoOx/Co) | 8.7 |
| selectivity (CuOx/Cu) | 0.5 |

1. A composition for selectively removing oxide compounds and etching residues of one or both of Co and Cu in the presence of one or more metals selected from the group consisting of Co, Cu, W, Ru, and Mos said composition comprising
(A) one or both of 1H-benzatriazole and 5-methyl-1H-benzotriazole, wherein a total amount of 1H-benzatriazole and 5-methyl-1H-benzotriazole is in a range of from 0.5% to 5%;
(B) one or both of histidine and chlorhexidine, wherein a total amount of histidine and chlorhexidine is in a range of from 500 ppm to 2000 ppm;
(C) one or both of lactic acid and glycolic acid wherein a total amount of lactic acid and glycolic acid is in a range of from 0.01% to 0.1%;
(D) one or both of N-formyl-morpholine and dimethylsulfoxide wherein a total amount of N-formyl-morpholine and dimethylsulfoxide is in a range of from 5% to 20%; and
(E) water,
in each case based on the sum of the masses of constituents (A), (B), (C), (D) and (E),
wherein a total concentration of compounds comprising a fluorine-containing anion is 0.0008 wt % or less based on the total mass of the composition, and
wherein said composition having has a pH value of less than 6.

2. The composition according to claim 1, wherein the total concentration of compounds comprising a fluorine-containing anion is 0.0005 wt % or less based on the total mass of the composition.

3. The composition according to claim 1, wherein said composition having has a pH value in the range of from 2 to 5.5.

4-9. (canceled)

10. A method of using a composition according to claim 1, the method comprising using the composition for selectively removing oxide compounds and etching residues of one or both of Co and Cu in the presence of one or more metals selected from the group consisting of Co, Cu, W, Ru and Mo in a process for a manufacture of a semiconductor device.

11. A process for manufacturing a semiconductor device, comprising a step of selectively removing oxide compounds and etching residues of one or both of Co and Cu in the presence of one or more metals selected from the group consisting of Co, Cu, W, Ru and Mo by applying the composition according to claim 1.

12. The process according to claim 11, wherein the semiconductor device is manufactured by means of sub-7 nm IC process technology.

13. The process according to claim 11, wherein the oxide compounds comprise oxides of one or both of Cu and Co;
and/or
wherein the etching residues comprise fluorides of one or both of Cu and Co.

14. The process according to claim 11, wherein the semiconductor device comprises
one or more interconnects comprising one or both of Co and Cu;
and/or
one or more interconnects comprising one or more of W, Ru and Mo;
and/or
one or more materials selected from the group consisting of polycrystalline Si, SiO₂ and Si₃N₄.

15. (canceled)

16. The composition according to claim 1, wherein the total concentration of compounds comprising a fluorine-containing anion is 0.0001 wt % or less based on the total mass of the composition.

17. The composition according to claim 1, wherein said composition has a pH value in the range of 2.5 to 4.

18. The method according to claim 10, wherein the semiconductor device is manufactured by means of a sub-7 nm IC process technology.
